(19) United States
(12) Patent Application Publication
(10) Pub. No.: US 2026/0068720 A1
(43) Pub. Date: Mar. 5, 2026

(54) Semiconductor Package Comprising Two Semiconductor Transistor Dies Connected Together to Form an Electrical Half-Bridge Circuit

(71) Applicant: Infineon Technologies Austria AG, Villach (AT)

(72) Inventors: Joo Teng Teoh, Melaka (MY); Chiao Eing Lim, Muar (MY); Sin Fah Yap, Parit (MY); Chii Shang Hong, Bukit Katil (MY)

(21) Appl. No.: 19/302,283

(22) Filed: Aug. 18, 2025

(30) Foreign Application Priority Data
Sep. 5, 2024 (DE) 102024125516.1

(51) Int. Cl. H01L 23/538; H01L 23/00; H01L 23/31; H01L 23/367; H01L 23/498; H01L 25/07

(52) U.S. Cl. CPC H01L 23/5386

(57) ABSTRACT

A semiconductor package includes a leadframe comprising first leads and second leads, a substrate connected between the first leads and the second leads, a base plate, a first semiconductor transistor die connected between the base plate and the substrate and including a first source pad, a first drain pad, and a first gate pad, a second semiconductor transistor die connected between the base plate and the substrate and comprising a second source pad, a second drain pad, and a second gate pad, wherein the first semiconductor die and the second semiconductor die are interconnected to form a half-bridge circuit, wherein the first source pad of the first semiconductor die is electrically connected with the second drain pad of the second semiconductor die, an encapsulant embedding the first semiconductor die, the second semiconductor transistor die, and horizontal portions of the first leads and the second leads.

### TECHNICAL FIELD

The present disclosure is related to a semiconductor package and a semiconductor module comprising the same.

### BACKGROUND

Power semiconductor transistors can be electrically connected together to form an electrical circuit such as a half-bridge circuit. A power semiconductor circuit of this kind is ideally housed in a common package with an encapsulant embedding the power semiconductor transistor dies. For the optimum performance of such an electrical device two aspects are of particular importance especially for achieving fast switching of high currents. Firstly, the shortest possible connection distances between the electrical components to avoid parasitic effects. And secondly, efficient dissipation of the heat generated during operation of the power circuit.

### SUMMARY

A first aspect of the present disclosure is related to a semiconductor package comprising a leadframe comprising first leads and second leads, a substrate connected between the first leads and the second leads, a base plate, a first semiconductor transistor die connected between the base plate and the substrate and comprising a first source pad, a first drain pad, and a first gate pad, a second semiconductor transistor die connected between the base plate and the substrate and comprising a second source pad, a second drain pad, and a second gate pad, wherein the first semiconductor die and the second semiconductor die are interconnected to form a half-bridge circuit, wherein the first source pad of the first semiconductor die is electrically connected with the second drain pad of the second semiconductor die, an encapsulant embedding the first semiconductor die, the second semiconductor transistor die, and horizontal portions of the first leads and the second leads.

According to embodiment of the semiconductor package according to the first aspect, each one of the first semiconductor transistor die and the second semiconductor transistor die comprises a lateral transistor comprising a load current path in a direction parallel to one of the main surfaces of the semiconductor transistor die. According to an example thereof each one of the first semiconductor transistor die and the second semiconductor transistor die comprises a high electron mobility transistor (HEMT).

Furthermore one or both of the first semiconductor transistor die and the second semiconductor transistor die can be a wide band gap semiconductor transistor die, in particular a GaN or a SiC transistor die.

Furthermore the first semiconductor transistor die and the second semiconductor transistor die are configured as power semiconductor transistor dies. A power transistor is a switching device that is rated to accommodate voltages of at least 20 V (volts) and more commonly on the order of 100V, 600 V, 1200V or more and/or is rated to accommodate currents of at least 1 A (amperes) and more commonly on the order of 10 A, 50 A, 100 A or even more.

According to embodiment of the semiconductor package according to the first aspect, a bottom side of the substrate is patterned for connecting the first source pad of the first semiconductor die with the second drain pad of the second semiconductor die to form a node of the half-bridge circuit. In particular, a bottom side of the substrate is further patterned for connecting the node of the half-bridge circuit with one of the first leads or one of the second leads.

According to embodiment of the semiconductor package according to the first aspect, a bottom side of the substrate is further patterned for connecting the first drain pad of the first semiconductor die, the second source pad of the second semiconductor pad, the first gate pad of the first semiconductor die, and the second gate pad of the second semiconductor die to respective ones of the first leads or ones of the second leads.

According to an embodiment of the semiconductor package according to the first aspect, one or both of the substrate and the base plate is one of a direct copper bond (DCB), an active metal braze (AMB), or an insulated metal substrate (IMS).

According to an embodiment of the semiconductor package according to the first aspect, the base plate is a single piece of metal, in particular copper.

According to an embodiment of the semiconductor package according to the first aspect, the base plate is exposed to the outside.

According to an embodiment of the semiconductor package according to the first aspect, a top side of the substrate is exposed to the outside.

According to an embodiment of the semiconductor package according to the first aspect, the first leads and the second leads extend out of the encapsulant and are bent down to the bottom side of the package.

Due to the fact that the first and second leads are disposed outside the encapsulant with certain length, in some embodiment even below the encapsulant, after mounting the semiconductor package onto a PCB the leads are more flexible to absorb any kind of mechanical stress between the semiconductor device and the PCB, which can increase board level reliability. Leaded packages can have long leads extending below the bottom surface of the package, but also possible to flush with the bottom surface of the package. It improves the TCOB (Temperature cycling on Board) mainly due to its length and flexibility of the material.

One or both of the first leads and the second leads may comprise a gullwing shape.

A second aspect of the present disclosure is related to a semiconductor module, comprising a semiconductor package according to the first aspect and a heat sink attached to a top side of the substrate.

The heat sink may be attached to the substrate by a solder material, a glue or a thermal interface material. Furthermore it may be attached by the manufacturer of the semiconductor package or on the customer side.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description.

The elements of the drawings are not necessarily to scale relative to each other. Like reference numerals designate corresponding similar parts.

FIG. 1 comprises FIGS. 1A and 1B and shows cross-sectional views of examples of a semiconductor package according to the first aspect with a metallic plate as the base plate (FIG. 1A) and a direct copper bond as the base plate (FIG. 1B).

FIG. 2 comprises FIGS. 2A and 2B and shows a top view on the leadframe and the semiconductor dies from a plane as indicated in FIG. 1A (FIG. 2A), and an equivalent circuit diagram of a half-bridge circuit (2B).

FIG. 3 shows a cross-sectional view of a semiconductor module as shown in FIG. 1A mounted on a printed circuit board on a customer's side.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Further, the word “over” used with regard to a part, element or material layer formed or located “over” a surface may be used herein to mean that the part, element or material layer be located (e.g. placed, formed, deposited, etc.) “indirectly on” the implied surface with one or more additional parts, elements or layers being arranged between the implied surface and the part, element or material layer. However, the word “over” used with regard to a part, element or material layer formed or located “over” a surface may, optionally, also have the specific meaning that the part, element or material layer be located (e.g. placed, formed, deposited, etc.) “directly on”, e.g. in direct contact with, the implied surface.

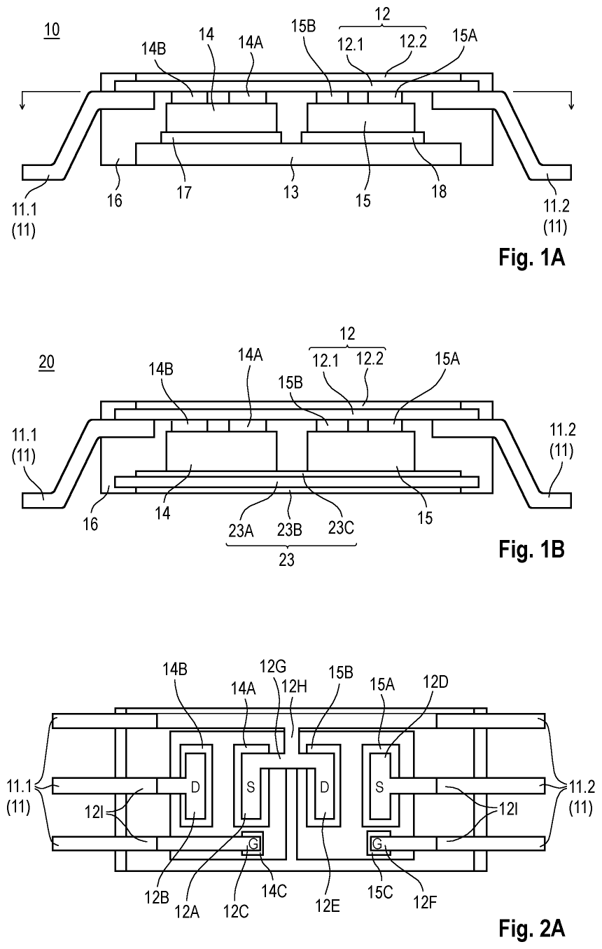

FIG. 1 comprises FIGS. 1A and 1B and shows cross-sectional views of examples of a semiconductor package according to the first aspect with a metallic plate as the base plate (FIG. 1A) and a direct copper bond as the base plate (FIG. 1B).

The semiconductor package 10 as shown in FIG. 1A comprises a leadframe 11 comprising first leads 11.1 and second leads 11.2, a direct copper bond (DCB) 12 connected between the first leads 11.1 and the second leads 11.2, and a metallic base plate 13. The DCB 12 comprises a ceramic layer 12.1 and a metallic layer 12.2, in particular of copper, on top of the ceramic layer 12.1, and another metallic layer, in particular of copper, (not shown) on the bottom of the ceramic layer 12.1. This lower metallic layer is patterned in a particular way which will be explained later. Instead of a DCB 12 also an active metal braze (AMB), or an insulated metal substrate (IMS) can be used.

The semiconductor package 10 furthermore comprises a first semiconductor transistor die 14 comprising a first source pad 14A, a first drain pad 14B, and a first gate pad 14C, and a second semiconductor transistor die 15 and comprising a second source pad 15A, a second drain pad 15B, and a second gate pad 15C. The first semiconductor die 14 and the second semiconductor die 15 are interconnected to form a half-bridge circuit, wherein the first source pad 14A of the first semiconductor die 14 is electrically connected with the second drain pad 15B of the second semiconductor die 15.

Each one of the first semiconductor transistor die 14 and the second semiconductor transistor die 15 comprises a lateral transistor comprising a load current path in a direction parallel to one of the main surfaces of the semiconductor transistor die. Accordingly the source, drain and gate pads are disposed at the upper main face of the semiconductor dies. Furthermore each one of the first semiconductor transistor die 14 and the second semiconductor transistor die 15 may comprise a high electron mobility transistor (HEMT).

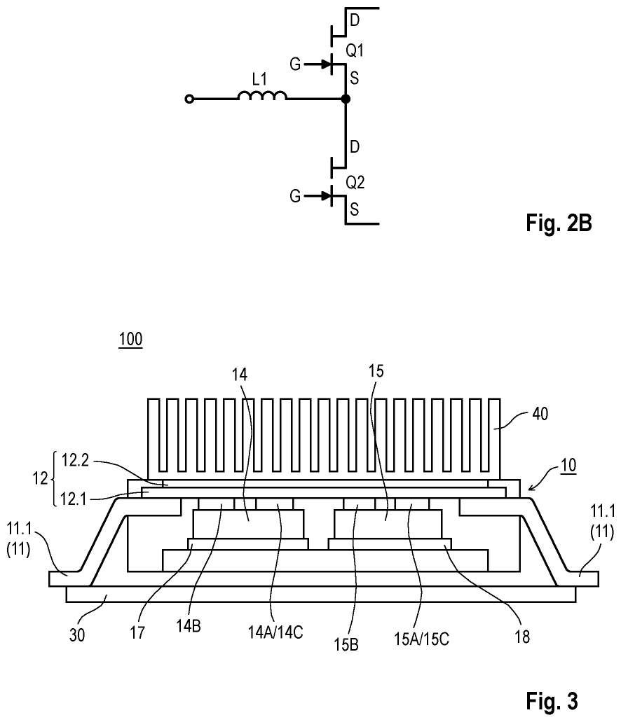

An example of such a half-bridge circuit is shown in FIG. 2B in the form of the equivalent circuit diagram. The semiconductor transistors Q1 and Q2 correspond to the semiconductor transistor dies denoted with the reference signs 14 and 15 in FIGS. 1A and 1B. An inductor L is connected with a node between the transistors Q1 and Q2.

The first semiconductor die 14 and the second semiconductor die 15 are connected on their upper sides with their respective source, drain and gate pads with connection areas of the bottom layer of the DCB 12 as will be shown further below in connection with FIG. 2A. With their lower sides the first semiconductor die 14 and the second semiconductor die 15 are connected with the base plate 13 via layers 17 and 18, in particular glue layers, in particular non-conductive glue layers.

The semiconductor package 10 as shown in FIG. 1A further comprises an encapsulant 16 embedding the first semiconductor die 14, the second semiconductor transistor die 15, and horizontal portions of the first leads 11.1 and the second leads 11.2.

The encapsulant 16 may be comprised of a conventional mold compound like, for example, a resin material, in particular an epoxy resin material. Moreover, the encapsulant 16 can be made of a thermally conductive material to allow efficient heat dissipation to external application heat sinks. The material of the encapsulant 16 can, in particular, comprise a resin like an epoxy resin material filled with particles like, for example, Sio or other ceramic particles, or thermally conductive particles like, for examples, Al₂O₃, BN, AlN, Si₃N₄, diamond, or any other thermally conductive particles.

FIG. 2 comprises FIGS. 2A and 2B and shows a top view on the leadframe and the semiconductor dies from a plane as indicated in FIG. 1A (FIG. 2A), and an equivalent circuit diagram of a half-bridge circuit (2B).

As can be seen in FIG. 2A the bottom layer of the DCB 12 is patterned to form connection areas 12A, 12B, and 12C. A first source connection area 12A is connected with the first source pad 14A of the first semiconductor transistor die 14, a first drain connection area 12B is connected with the first drain pad 14B of the first semiconductor transistor die, and a first gate connection area 12C is connected with the first gate pad 14C of the first semiconductor transistor die 14. Likewise a second source connection area 12D is connected with the second source pad 15A of the second semiconductor transistor die 15, a second drain connection area 12E is connected with the second drain pad 15B of the second semiconductor transistor die 15, and a second gate connection area 12F is connected with the second gate pad 15C of the second semiconductor transistor die 15.

As can further be seen in FIG. 2A, the bottom layer of the DCB 12 further comprises a source/drain connection area 12G which is connected between the first source connection area 12A and the second drain connection area 12E for connecting the first source pad 14A of the first semiconductor die 14 with the second drain pad 15B of the second semiconductor die 15 to form a node of the half-bridge circuit.

As can further be seen in FIG. 2A, the bottom layer of the DCB 12 further comprises a node connection area 12H for connecting the node of the half-bridge circuit with a common lead of the first leads 11.1 and the second leads 11.2. Hence in this example the node is accessible from two sides of the package. However, it is also possible that the node is only connected with one of the first leads 11.1 or with one of the second leads 11.2 so that the node will be finally only accessible from one side of the package. In this way the customers could simplify their design.

As can further be seen in FIG. 2A, the bottom layer of the DCB 12 further comprises external connection areas 12I for connecting the first drain pad 14B of the first semiconductor die 14, the second source pad 15A of the second semiconductor die 15, the first gate pad 14C of the first semiconductor die 14, and the second gate pad 15C of the second semiconductor die 15 to respective ones of the first leads 11.1 or ones of the second leads 11.2.

The semiconductor package 20 as shown in FIG. 1B differs from the semiconductor package 10 only in the use of a different base plate. Instead of the metallic base plate 13 of the semiconductor package 10, the semiconductor package 20 has a direct copper bond (DCB) 23. This usually has a central ceramic layer 23A and metallic Cu layers 23B and 23C applied on both sides, in particular a first Cu layer 23B applied to the lower surface of the ceramic layer 23A and a second Cu layer 23C applied to the upper surface of the ceramic layer 23A. The upper Cu layer 23C may be divided into two parts as shown, wherein the first semiconductor die 14 is deposited on a left-side portion of the Cu layer 23C and the second semiconductor die 15 is deposited on the right-side portion of the Cu layer 23C. Instead of a DCB 23 also an active metal braze (AMB), or an insulated metal substrate (IMS) can be used.

The other components of the semiconductor package 20 can be similar or identical the corresponding components of the semiconductor package 10, so that identical reference numerals have been used.

One advantage of the present disclosure can be seen in the extremely short connection paths between the electrical components, through which parasitic inductances of the electrical connections between contact pads of the semiconductor transistor dies and external contacts can be minimized in the best possible way. These parasitic inductances lead to a delay in the power slew rates in the main current path between source and drain. Especially with high load currents and high temporal current changes, even parasitic inductances with values of a few nH can lead to significant voltage drops in the electrical connections. This leads directly to a limitation in performance of the device.

FIG. 3 shows a cross-sectional view of a semiconductor module as shown in FIG. 1A mounted on a printed circuit board on a customer's side.

The semiconductor module 100 as shown in FIG. 3 comprises a semiconductor package 10 according to FIG. 1A mounted on a printed circuit board 30 and a heat sink 40 attached to a top side of the DCB 12, in particular to the upper Cu layer 12.2 of the DCB 12.

The heat sink 40 can be attached to the DCB 12 by a solder material or by a glue or a thermal interface material.

Thus, a significant advantage of the present disclosure is the use of a DCB 12 as the uppermost component of a semiconductor package 10 or 20 of the type described. As described, the load currents between the semiconductor transistor dies 14 and 15 flow between the patterned connection areas 12A, 12B, 12G, 12E and 12D of the lower metallic layer of the DCB 12. The heat generation thus takes place at a significantly short distance from the heat dissipating upper layer 12.2 of the DCB 12. The heat flows from the structured connection areas 12A, 12B, 12G, 12E and 12D of the lower metallic layer of the DCB 12 or from the spaces between them through the thermally conductive ceramic layer 12.1 of the DCB 12 to the full-surface upper metallic layer 12.2 of the DCB 12. This represents a major advantage over comparable known semiconductor packages, in which only a TIM (thermal interface material) layer applied to the upper surface of the package ensures heat dissipation. The upper full-surface metallic layer 12.2 of the PCB 12, on the other hand, ensures far more efficient heat dissipation, especially if the customer has the option of applying a heat sink to the upper layer 12.2 of the PCB 12 by means of a soldering process.

In the following specific examples of the present disclosure are described.

Example 1 is a semiconductor package comprising a leadframe comprising first leads and second leads, a substrate connected between the first leads and the second leads, a base plate, a first semiconductor transistor die connected between the base plate and the substrate and comprising a first source pad, a first drain pad, and a first gate pad, a second semiconductor transistor die connected between the base plate and the substrate and comprising a second source pad, a second drain pad, and a second gate pad, wherein the first semiconductor die and the second semiconductor die are interconnected to form a half-bridge circuit, wherein the first source pad of the first semiconductor die is electrically connected with the second drain pad of the second semiconductor die, an encapsulant embedding the first semiconductor die, the second semiconductor transistor die, and horizontal portions of the first leads and the second leads.

Example 2 is the semiconductor package according to Example 1, wherein a bottom side of the substrate is patterned for connecting the first source pad of the first semiconductor die with the second drain pad of the second semiconductor die to form a node of the half-bridge circuit.

Example 3 is the semiconductor package according to Example 2, wherein a bottom side of the substrate is further patterned for connecting the node of the half-bridge circuit with one of the first leads or one of the second leads.

Example 4 is the semiconductor package according to any one of the preceding Examples, wherein a bottom side of the substrate is further patterned for connecting the first drain pad of the first semiconductor die, the second source pad of the second semiconductor pad, the first gate pad of the first semiconductor die, and the second gate pad of the second semiconductor die to respective ones of the first leads or ones of the second leads.

Example 5 is the semiconductor package according to any one of the preceding Examples, wherein the substrate is one of a direct copper bond (DCB), an active metal braze (AMB), or an insulated metal substrate (IMS).

Example 6 is the semiconductor package according to any one of the preceding Examples, wherein the base plate is exposed to the outside.

Example 7 is the semiconductor package according to any one of the preceding Examples, wherein the base plate is a single piece of metal, in particular copper.

Example 8 is the semiconductor package according to any one of Examples 1 to 6, wherein the base plate is one of a direct copper bond (DCB), an active metal braze (AMB), or an insulated metal substrate (IMS).

Example 9 is the semiconductor package according to any one of the preceding Examples, wherein a top side of the substrate is exposed to the outside.

Example 10 is the semiconductor package according to any one of the preceding Examples, wherein each one of the first semiconductor transistor die and the second semiconductor transistor die comprises a lateral transistor comprising a load current path in a direction parallel to one of the main surfaces of the semiconductor transistor die.

Example 11 is the semiconductor package according to any one of the preceding Examples, wherein the first leads and the second leads extend out of the encapsulant and are bent down to the bottom side of the package.

Example 12 is the semiconductor package according to Example 11, wherein the first leads and the second leads comprise a gullwing shape.

Example 12 is a semiconductor module, comprising a semiconductor package according to anyone of the preceding Examples, and a heat sink attached to a top side of the substrate.

Example 13 is the semiconductor module according to Example 12, wherein the heat sink is attached to the substrate by a solder material.

Example 14 is the semiconductor module according to Example 13, wherein the heat sink is attached to the substrate by a glue or a thermal interface material.

Example 15 is the semiconductor module according to any one of the Examples 12 to 14, further comprising a printed circuit board (PCB), wherein the semiconductor package is mounted on the PCB.

In addition, while a particular feature or aspect of an embodiment of the disclosure may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. Furthermore, it should be understood that embodiments of the disclosure may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. A semiconductor package comprising:
a leadframe comprising first leads and second leads;
a substrate connected between the first leads and the second leads;
a base plate;
a first semiconductor transistor die connected between the base plate and the substrate and comprising a first source pad, a first drain pad, and a first gate pad;
a second semiconductor transistor die connected between the base plate and the substrate and comprising a second source pad, a second drain pad, and a second gate pad; wherein
the first semiconductor die and the second semiconductor die are interconnected to form a half-bridge circuit, wherein the first source pad of the first semiconductor die is electrically connected with the second drain pad of the second semiconductor die;
an encapsulant embedding the first semiconductor die, the second semiconductor transistor die, and horizontal portions of the first leads and the second leads;
wherein a bottom side of the substrate is patterned for connecting the first source pad of the first semiconductor die with the second drain pad of the second semiconductor die to form a node of the half-bridge circuit, and
wherein each one of the first semiconductor transistor die and the second semiconductor transistor die comprises a lateral transistor.

2. The semiconductor package according to claim 1, wherein a bottom side of the substrate is further patterned for connecting the node of the half-bridge circuit with one of the first leads or one of the second leads.

3. The semiconductor package according to claim 1, wherein a bottom side of the substrate is further patterned for connecting the first drain pad of the first semiconductor die, the second source pad of the second semiconductor pad, the first gate pad of the first semiconductor die, and the second gate pad of the second semiconductor die to respective ones of the first leads or ones of the second leads.

4. The semiconductor package according to claim 1, wherein the substrate is one of a direct copper bond (DCB), an active metal braze (AMB), or an insulated metal substrate (IMS).

5. The semiconductor package according to claim 1, wherein the base plate is exposed to the outside.

6. The semiconductor package according to claim 1, wherein the base plate is a single piece of metal, in particular copper.

7. The semiconductor package according to claim 1, wherein the base plate is one of a direct copper bond (DCB), an active metal braze (AMB), or an insulated metal substrate (IMS).

8. The semiconductor package according to claim 1, wherein a top side of the substrate is exposed to the outside.

9. The semiconductor package according to claim 1, wherein the first leads and the second leads extend out of the encapsulant and are bent down to the bottom side of the package.

10. The semiconductor package according to claim 1, wherein the first leads and the second leads comprise a gullwing shape.

11. A semiconductor module, comprising a semiconductor package according to claim 1, and a heat sink attached to a top side of the substrate.

12. The semiconductor module according to claim 11, wherein the heat sink is attached to the substrate by a solder material.

13. The semiconductor module according to claim 11, wherein the heat sink is attached to the substrate by a glue or a thermal interface material.

14. The semiconductor module according to claim 11, further comprising a printed circuit board (PCB), wherein the semiconductor package is mounted on the PCB.
